(19) United States
(12) Patent Application Publication
(10) Pub. No.: US 2010/0075563 A1
(43) Pub. Date: Mar. 25, 2010

(54) METHOD OF MANUFACTURING FLAT-PANEL DISPLAY DEVICE, APPARATUS FOR MANUFACTURING FLAT-PANEL DISPLAY DEVICE, AND FLAT-PANEL DISPLAY DEVICE

(75) Inventors: Tomohiro MATSUI, Yokohama-shi (JP); Masaaki Furuya, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/555,422

(22) Filed: Sep. 8, 2009

(30) Foreign Application Priority Data
Sep. 24, 2008 (JP) 2008-243878

(51) Int. Cl. H01J 9/20; H01J 9/38; H05K 5/00

(52) U.S. Cl. 445/25; 445/70; 361/679.01

(57) ABSTRACT

Disclosed is a method of manufacturing a flat-panel display device, includes: laminating a thermosetting resin film on a sealing substrate; stacking the sealing substrate having the thermosetting resin film laminated thereon, and an element substrate having a light-emitting element together under a vacuum atmosphere with the thermosetting resin film and the light-emitting element facing inwardly, and with a frame-shaped sealing material around the thermosetting resin film interposed between the two substrates; joining the sealing substrate and the element substrate together under a vacuum atmosphere by the sealing material situated between the sealing substrate and the element substrate stacked together; and heat-curing the thermosetting resin film situated between the sealing substrate and the element substrate stacked together, under an air atmosphere.

### CROSS REFERENCE OF THE RELATED APPLICATION

This application is based on and claims the benefit of priority from Japanese Patent Application No. 2008-243878, filed on Sep. 24, 2008; the entire contents of which are incorporated herein by reference.

### BACKGROUND OF THE INVENTION

1. Field of the Invention

The present invention relates to a method of manufacturing a flat-panel display device, an apparatus for manufacturing a flat-panel display device, and a flat-panel display device.

2. Description of the Related Art

A flat-panel display device is used in various kinds of equipment such as a computer's display and a mobile terminal. An organic EL (electroluminescence) display device, for example, has been developed as one type of flat-panel display device. The organic EL display device is the display device capable of having a thinner body than a liquid crystal display device, a plasma display device, or the like and capable of spontaneous light emission as is the case with the plasma display device.

In the flat-panel display device, a sealing substrate and an element substrate are joined together by a frit material that acts as a sealing material, thereby to seal in a light-emitting element on the element substrate, for the purpose of preventing the light-emitting element from being deteriorated by moisture and oxygen (See JP-A No. 2007-115692 (KOKAI), JP-A No. 2007-227340 (KOKAI) and JP-A No. 2007-140061 (KOKAI), for example). Here, for the purpose of preventing interference fringes from being generated due to a space between the sealing substrate and the light-emitting element, there have been proposed a method that includes providing a film between the sealing substrate and the light-emitting element (see JP-A No. 2007-115692 (KOKAI), for example) and a method that includes widening a distance therebetween to such an extent that no interference fringes are generated (see JP-A No. 2007-227340 (KOKAI), for example). Moreover, there has been proposed a method that includes reinforcing the periphery of the frit material by using a resin, for the purpose of preventing damage due to a shock to the substrate (See JP-A No. 2007-140061 (KOKAI), for example).

However, the above-mentioned methods adopt a structure in which the space exists between the sealing substrate and the light-emitting element, or a structure in which the sealing substrate and the element substrate are joined together only by the frit material, thereby failing to ensure sufficient strength. For this reason, the damage by the shock occasionally occurs, and hence flat-panel display devices thus configured have only low product reliability. Moreover, the frit material, before sealing, can possibly be contaminated by the resin or the film, and this surface contamination of the frit reduces sealing strength, which also results in low product reliability. Furthermore, the need for a reinforcement process to be performed around the periphery of the frit material makes a manufacturing process complicated.

### SUMMARY OF THE INVENTION

An object of the present invention is to provide a method of manufacturing a flat-panel display device, an apparatus for manufacturing a flat-panel display device, and a flat-panel display device, capable of achieving an improvement in product reliability and a simplification of a manufacturing process.

A first aspect according to an embodiment of the present invention is a method of manufacturing a flat-panel display device, includes: laminating a thermosetting resin film on a sealing substrate; stacking the sealing substrate having the thermosetting resin film laminated thereon, and an element substrate having a light-emitting element together under a vacuum atmosphere with the thermosetting resin film and the light-emitting element facing inwardly, and with a frame-shaped sealing material around the thermosetting resin film interposed between the two substrates; joining the sealing substrate and the element substrate together under a vacuum atmosphere by the sealing material situated between the sealing substrate and the element substrate stacked together; and heat-curing the thermosetting resin film situated between the sealing substrate and the element substrate stacked together, under an air atmosphere.

A second aspect according to an embodiment of the present invention is an apparatus for manufacturing a flat-panel display device, includes: a hermetic vacuum chamber having an openable/closable door; a stage provided in the vacuum chamber; a heater provided in the vacuum chamber and configured to heat the stage; an elastic sheet provided in the vacuum chamber, and configured to be movable so as to partition the vacuum chamber into a pressure chamber that forms an enclosed space and an accommodation chamber that accommodates the heater and the stage; a sheet movement mechanism configured to effect movement of the elastic sheet from outside the vacuum chamber; an evacuation unit configured to evacuate the vacuum chamber; and a first supply unit configured to supply an inert gas to the pressure chamber.

A third aspect according to an embodiment of the present invention is a flat-panel display device manufactured by the manufacturing method according to the first aspect.

### BRIEF DESCRIPTION OF THE DRAWINGS

FIG. 1 is a sectional view of a first process showing a process for manufacturing a flat-panel display device according to a first embodiment of the present invention.

FIG. 2 is a sectional view of a second process.

FIG. 3 is a sectional view of a third process.

FIG. 4 is a sectional view of a fourth process.

FIG. 5 is a sectional view of a fifth process.

FIG. 6 is a sectional view of a sixth process.

FIG. 7 is a plan view showing a portion of an apparatus for manufacturing a flat-panel display device according to the first embodiment of the present invention.

FIG. 8 is a schematic view showing a general configuration of a vacuum laminator included in the manufacturing apparatus shown in FIG. 7.

FIG. 9 is an explanatory view of first operation, useful in explaining laminating operation performed by the vacuum laminator shown in FIG. 8.

FIG. 10 is an explanatory view of second operation.

FIG. 11 is an explanatory view of third operation.

FIG. 12 is an explanatory view of fourth operation.

FIG. 13 is a sectional view of a first process showing a process for manufacturing a flat-panel display device according to a second embodiment of the present invention.

FIG. 14 is a sectional view of a second process.

FIG. 15 is a sectional view of a third process.

FIG. 16 is a sectional view of a fourth process.

FIG. 17 is a sectional view of a fifth process.

FIG. 18 is a sectional view of a first process showing a process for manufacturing a flat-panel display device according to a third embodiment of the present invention.

FIG. 19 is an explanatory view useful in explaining the mounting and deformed spreading of a first sealant.

FIG. 20 is an explanatory view useful in explaining the mounting of a second sealant.

FIG. 21 is an explanatory view useful in explaining the mounting of a third sealant.

FIG. 22 is an explanatory view useful in explaining the mounting of a fourth sealant.

### DESCRIPTION OF THE PREFERRED EMBODIMENTS

### First Embodiment

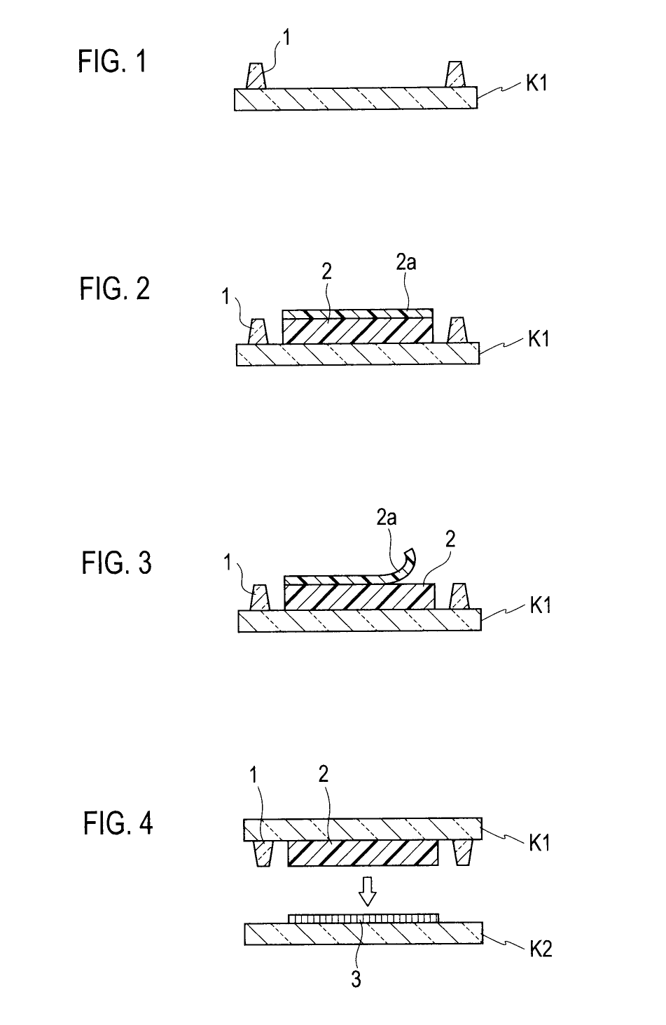

A first embodiment of the present invention will be described with reference to FIGS. 1 to 12.

### (A Method of Manufacturing a Flat-Panel Display Device)

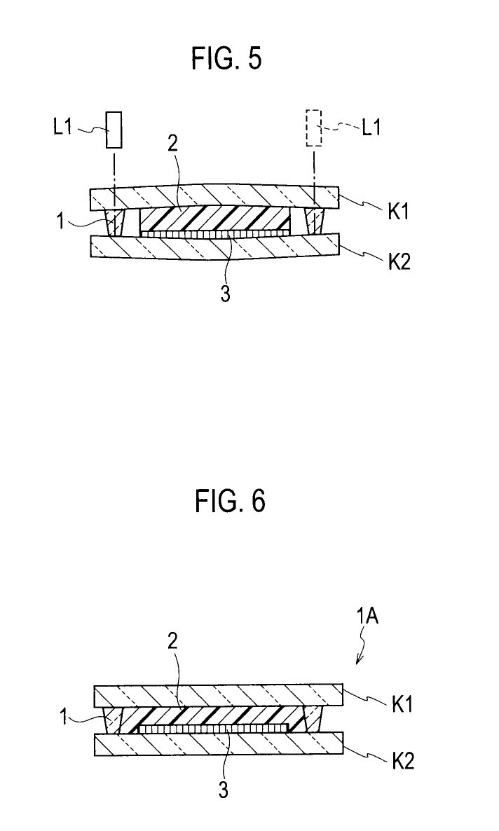

A process for manufacturing the flat-panel display device according to the first embodiment of the present invention includes a coating and baking process for performing coating and baking of a frit material 1 in the shape of a frame on a sealing substrate K1, as shown in FIG. 1; a film laminating process for mounting and laminating a thermosetting resin film 2 having a protective sheet 2a, both on the sealing substrate K1 and inside the frame-shaped frit material 1, as shown in FIG. 2; a sheet delaminating process for delaminating the protective sheet 2a on the thermosetting resin film 2, as shown in FIG. 3; a lamination process for laminating the sealing substrate K1 having the thermosetting resin film 2 laminated thereon, to an element substrate K2 having plural light-emitting elements 3, as shown in FIG. 4; a frit bonding process for bonding the frit material 1 to the element substrate K2 by melting the frame-shaped frit material 1 situated between the sealing substrate K1 and the element substrate K2 laminated together, as shown in FIG. 5; and a film curing process for heat-curing the thermosetting resin film 2 situated between the sealing substrate K1 and the element substrate K2 having the frit material 1 bonded thereto, as shown in FIG. 6.

In the coating and baking process, as shown in FIG. 1, the frit material 1 that acts as a sealing material is coated in the shape of the frame around a predetermined region on the sealing substrate K1. Subsequently, the sealing substrate K1 coated with the frit material 1 is placed in a baking furnace. Thus, the frame-shaped frit material 1 is baked on the sealing substrate K1. The frit material 1 on the sealing substrate K1 is trapezoidal, for example, in cross section. Baking conditions are, by way of example, a temperature on the order of 320 degrees in an air atmosphere for pre-baking, and a temperature on the order of 420 degrees in an atmosphere of an inert gas such as nitrogen (N₂) for baking proper.

Here, a glass substrate or the like, for example, is used as the sealing substrate K1. Also, the width of the frit material 1 is of the order of 0.3 mm to 1.0 mm, for example, and the height thereof is designed equal to or a few micrometers less than the thickness of the thermosetting resin film 2.

In the film laminating process, as shown in FIG. 2, the thermosetting resin film 2 having the protective sheet 2a is mounted both on the sealing substrate K1 coated with the frit material 1 and inside the frame-shaped frit material 1. In this process, a film laminator 11b (to be described in detail later) is used, and the mounting of the film takes place in an atmosphere of an inert gas such as nitrogen. Subsequently, the thermosetting resin film 2 on the sealing substrate K1 is bonded and laminated to the sealing substrate K1, in intimate contact therewith, by being heated at a temperature on the order of 80 degrees, that is, at a temperature such that the thermosetting resin film 2 does not cure but softens on its surface. In this process, a vacuum laminator 11c (to be described in detail later) is used, and the heating of the film takes place in a vacuum atmosphere.

Here, the thermosetting resin film 2 functions as an anti-interference-fringe film to prevent interference fringes, and is a material to form a resin layer after panel formation. The thermosetting resin film 2, when heated, softens and sets by a chemical reaction. Once set by heating, the thermosetting resin film 2 does not melt even if reheated. The thermosetting resin film 2 according to this embodiment, in particular, is laminated on the substrate at a temperature such that its surface tackiness improves, and is the film of a type which temporarily softens and melts in the process of being heated to a temperature such that it sets wholly. Incidentally, the thickness of the thermosetting resin film 2 is of the order of 10 μm to 20 μm, for example.

In the sheet delaminating process, as shown in FIG. 3, the protective sheet 2a is delaminated from the thermosetting resin film 2 on the sealing substrate K1. In the sheet delaminating process, a sheet delaminating apparatus 11d (to be described in detail later) is used, and sheet delamination takes place in an atmosphere of an inert gas such as nitrogen. Incidentally, the protective sheet 2a is laminated on the thermosetting resin film 2, and acts as the sheet to protect the thermosetting resin film 2 from the outside air (or equivalently, dirt or dust deposits or the like) or external forces.

In the lamination process, as shown in FIG. 4, the sealing substrate K1 is turned upside down so that the thermosetting resin film 2 on the sealing substrate K1 faces the light-emitting elements 3 on the element substrate K2, and the sealing substrate K1 is mounted and laminated on the element substrate K2. In the lamination process, a laminator or the vacuum laminator 11c is used, and lamination takes place in a vacuum atmosphere. For instance, the sealing substrate K1 is supported by a retainer of the laminator, and the element substrate K2 is mounted on a stage of the laminator. Subsequently, alignment is provided between the sealing substrate K1 and the element substrate K2, and the stage having the element substrate K2 mounted thereon moves toward the retainer retaining the sealing substrate K1. Thus, the sealing substrate K1 and the element substrate K2 are laminated together under pressure and also in a vacuum atmosphere.

Here, the element substrate K2 has an organic EL circuit formed thereon, the circuit having the light-emitting elements 3 (e.g., organic light-emitting diode (OLED) elements) stacked one on top of another for each pixel, each element being formed of an organic light-emitting element film, an electrode layer that serves to feed a current through the element film, and so on. Also, the element substrate K2 is subject to control in an atmosphere of an inert gas under dew-point control, since the light-emitting elements 3 undergo deterioration by moisture or oxygen.

In the frit bonding process, as shown in FIG. 5, the frame-shaped frit material 1 situated between the sealing substrate K1 and the element substrate K2 laminated together is irradiated with laser light and thus melted to be bonded to the element substrate K2. In the frit bonding process, a laser sealing apparatus is used, and the laser light irradiation takes place in a vacuum atmosphere. A laser irradiation unit L1 (see FIG. 5) provided in the laser sealing apparatus, for example, is used to apply the laser light to the frame-shaped frit material 1 situated between the sealing substrate K1 and the element substrate K2 laminated together. Thus, the frit material 1 is melted to be bonded to the element substrate K2. In this way, the sealing substrate K1 and the element substrate K2 are joined together by the frit material 1.

Here, at the time of laser irradiation, the sealing substrate K1 and the element substrate K2 are pressurized in a direction in which they come into intimate contact with each other, or the sealing substrate K1 and the element substrate K2 are pressurized at their points opposite to the frit material 1, and the laser irradiation takes place. This enables reliable bonding of the frit material 1 to the element substrate K2.

In the film curing process, as shown in FIG. 6, the sealing substrate K1 and the element substrate K2 having the frit material 1 bonded thereto are placed in a baking furnace, and the thermosetting resin film 2 interposed therebetween is heat-cured. Baking conditions are, by way of example, a temperature on the order of 100 degrees in an air atmosphere for film curing proper. By this heating, the thermosetting resin film 2 temporarily softens and melts, spreads into an internal space formed by the frame-shaped frit material 1, the sealing substrate K1 and the element substrate K2, fills the internal space, and is cured. Thereby, a flat-panel display device 1A is brought to completion.

Here, the above-mentioned internal space is under a reduced pressure, and thus, the molten thermosetting resin film 2 spreads by being pressed by an atmospheric pressure acting on an outer surface of the panel of the sealing substrate K1 and the element substrate K2. When the thermosetting resin film 2 is cured, the sealing substrate K1 and the element substrate K2 are fixed by the thermosetting resin film 2 that fills the internal space, as well as by the frame-shaped frit material 1, and thus, sufficient strength can be achieved. Also, the spread of the thermosetting resin film 2 in the internal space varies depending on the viscosity of a film material and a gas pressure in the panel, and at the time of sealing, an atmospheric pressure and a curing temperature can be set to control the range of the spread of the resin.

According to the manufacturing method of the first embodiment of the present invention, as described above, the internal space of the flat-panel display device 1A is filled with the resin layer formed by the thermosetting resin film 2, and adhesion between the sealing substrate K1 and the element substrate K2 is improved, as compared to bonding only by the frit material 1. Therefore, sufficient strength can be ensured, as compared to an instance where the frit material 1 is used alone to hold adhesion. Thus, damage by shock can be suppressed, and product reliability can be improved. Moreover, before the laser irradiation, a gap can be provided between the thermosetting resin film 2 and the frit material 1 so that they do not come into contact with each other. Thus, deterioration of sealing strength by surface contamination of the frit can be suppressed, and the product reliability can be improved. Furthermore, a reinforcement process to be performed around the periphery of the frit material is not necessary. Thus, a simplification of a manufacturing process can be achieved.

Incidentally, the thermosetting resin film 2 is filled as the resin layer into a gap between the sealing substrate K1 and the element substrate K2, and the initial volume of the film (equal to the thickness of the film multiplied by the area of the film) may be set equal to the volumetric capacity of the frit frame thereby to make the thickness of the gap between the substrates uniform. Consequently, the interference fringes can be reliably prevented from occurring.

Also, the area of the film is reduced by increasing the thickness of the film, or the volumetric capacity of the frit frame is reduced by reducing the height of the frit. For this reason, the gap between the thermosetting resin film 2 and the frame-shaped frit material 1 can be increased. Thereby, when the thermosetting resin film 2 is mounted both on the sealing substrate K1 and inside the frame-shaped frit material 1, high alignment accuracy is not required. Thus, a simplification of mounting operation and a simplification of an apparatus can be achieved. Also, the gap can be increased, and thus, before the laser irradiation, a contact between the thermosetting resin film 2 and the frit material 1 can be prevented with reliability. Thus, the deterioration of the sealing strength by the surface contamination of the frit can be suppressed with reliability.

### (An Apparatus for Manufacturing a Flat-Panel Display Device)

Next, description will be given with regard to the apparatus for manufacturing the flat-panel display device. Here, description will be given with regard to a manufacturing apparatus 11 for performing the above-mentioned film laminating process and sheet delaminating process.

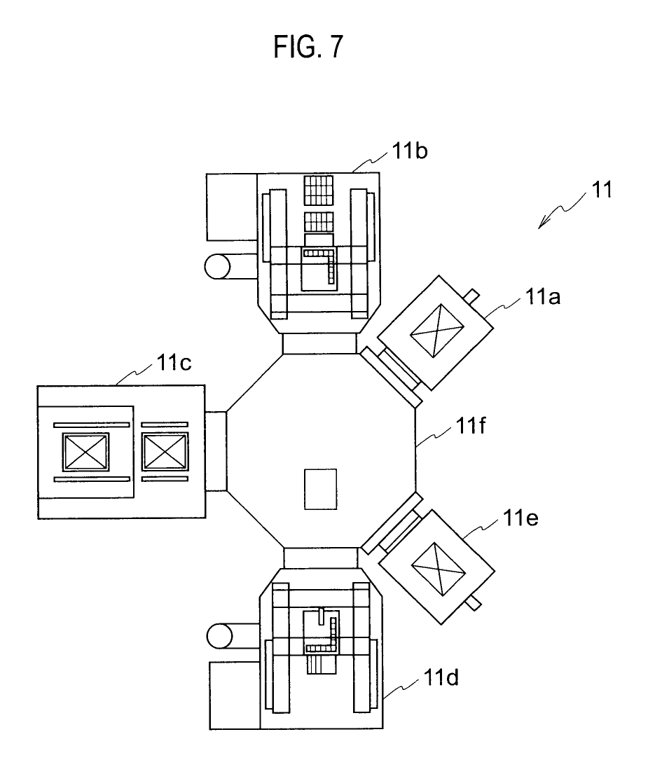

As shown in FIG. 7, the manufacturing apparatus 11 according to the first embodiment of the present invention includes a charging apparatus 11a that charges the sealing substrate K1 on which the frame-shaped frit material 1 is baked; the film laminator 11b that laminates the thermosetting resin film 2 having the protective sheet 2a both on the sealing substrate K1 and inside the frame-shaped frit material 1; the vacuum laminator 11c that laminates the thermosetting resin film 2 to the sealing substrate K1 in intimate contact therewith; the sheet delaminating apparatus 11d that delaminates the protective sheet 2a from the thermosetting resin film 2 on the sealing substrate K1; a dispenser 11e that dispenses the sealing substrate K1 that has undergone the sheet delamination; and a transport apparatus 11f that transports the sealing substrate K1 from one to another of the apparatuses. These apparatuses are shielded from the outside air, and the inside is basically maintained in an atmosphere of an inert gas such as nitrogen.

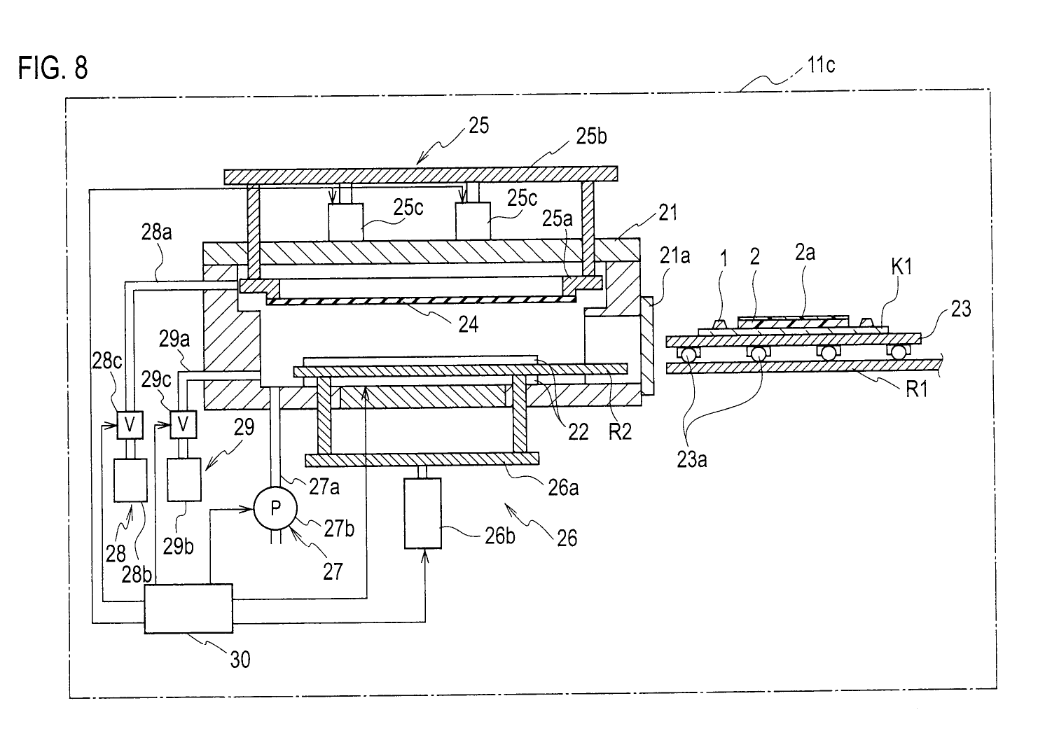

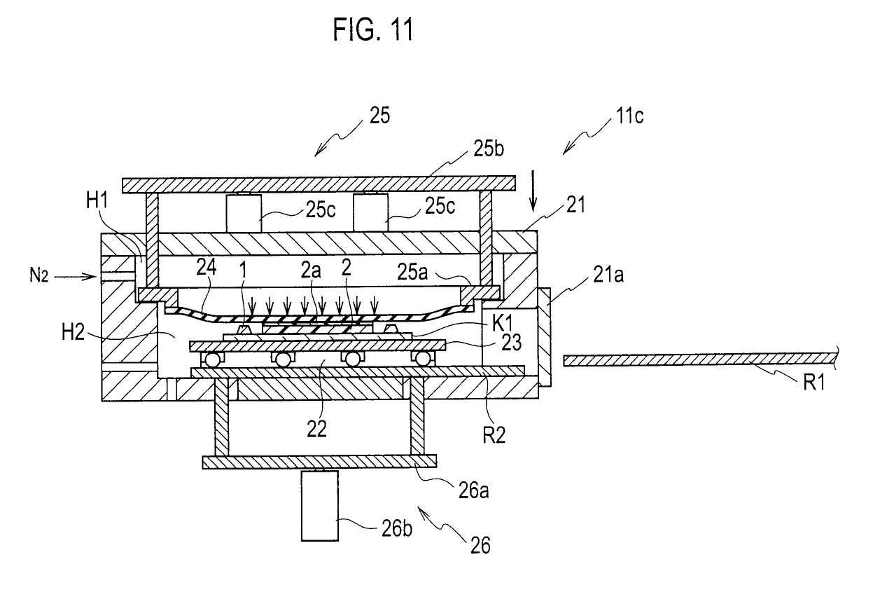

As shown in FIG. 8, the vacuum laminator 11c includes: a vacuum chamber 21 having an openable/closable door 21a; a heater 22 provided in the vacuum chamber 21; a stage 23 movably formed on the heater 22; an elastic sheet 24 formed movably to and away from the heater 22 provided in the vacuum chamber 21; a sheet movement mechanism 25 that effects movement of the elastic sheet 24 from outside the vacuum chamber 21; a stage movement mechanism 26 that effects movement of the stage 23 located on the heater 22 from outside the vacuum chamber 21; an evacuation unit 27 that evacuates the vacuum chamber 21; a first supply unit 28 that supplies the inert gas to a pressure chamber H1 (see FIG. 11) in the vacuum chamber 21; a second supply unit 29 that supplies the inert gas to an accommodation chamber H2 (see FIG. 11) in the vacuum chamber 21; and a controller 30 that controls parts.

The vacuum chamber 21 has the door 21a as a sliding door formed in an openable/closable fashion. The movable stage 23 is transported through the door 21a into the vacuum chamber 21 and onto the heater 22, and the sealing substrate K1 on the stage 23 is transported into the vacuum chamber 21. Incidentally, the frame-shaped frit material 1 is baked on the sealing substrate K1, and the thermosetting resin film 2 having the protective sheet 2a is laminated inside the frit material 1. Subsequently, with the door 21a closed, the vacuum chamber 21 is evacuated by the evacuation unit 27 and is thereby placed under a lower pressure than an atmospheric pressure (e.g., under a vacuum).

The heater 22 heats the sealing substrate K1 on the stage 23 through the stage 23 thereby to soften the thermosetting resin film 2 on the sealing substrate K1 and improve the adhesion of the thermosetting resin film 2. The heater 22 is electrically connected to the controller 30 and is controlled by the controller 30 so as to be kept constant at a temperature such that the thermosetting resin film 2 does not cure but softens on its surface.

The stage 23 has plural rotatable wheels 23a, the sealing substrate K1 is mounted on the stage 23 by a substrate transport robot in the transport apparatus 11f, and the stage 23 is formed movably from a pair of rails R1 through an opening by the open door 21a to a pair of rails R2 in the vacuum chamber 21.

The elastic sheet 24 is formed movably in a direction to and away from the heater 22 so that the vacuum chamber 21 can be partitioned into the pressure chamber H1 that is the closed space (see FIG. 11), and the accommodation chamber H2 (see FIG. 11) accommodating the heater 22 and the stage 23. An elastic material such, for example, as silicon or viton is used as the elastic sheet 24.

The sheet movement mechanism 25 is configured of a frame-shaped retainer 25a that retains the outer edge of the elastic sheet 24, a support 25b that supports the retainer 25a so that the retainer 25a can move upward and downward, and an upward and downward movement mechanism 25c that effects movement of the support 25b in an upward and downward direction. The upward and downward movement mechanism 25c is electrically connected to the controller 30, and effects upward and downward movements of the support 25b and the retainer 25a through the elastic sheet 24 under control of the controller 30. When the support 25b moves upward and downward by the upward and downward movement mechanism 25c, the elastic sheet 24 retained by the retainer 25a also moves upward and downward relative to the heater 22. At this time, the retainer 25a moves downward and abuts against a frame-shaped projection formed on an inner wall of the vacuum chamber 21 at a predetermined location. Thereby, the vacuum chamber 21 is partitioned into the pressure chamber H1 and the accommodation chamber H2 by the elastic sheet 24. Incidentally, an abutment surface of the projection is provided with an O-ring or the like as a hermeticity holding member, in order to hold hermeticity at the time of partition into the pressure chamber H1 and the accommodation chamber H2.

The stage movement mechanism 26 is configured of the pair of rails R2 provided in the vacuum chamber 21, a support 26a that supports the pair of rails R2 so that the pair of rails R2 can move upward and downward, and an upward and downward movement mechanism 26b that effects upward and downward movements of the support 26a. The upward and downward movement mechanism 26b is electrically connected to the controller 30, and effects upward and downward movements of the stage 23 through the support 26a and the pair of rails R2 under control of the controller 30. When the support 26a moves upward and downward by the upward and downward movement mechanism 26b, the stage 23 on the pair of rails R2 also moves upward and downward relative to the heater 22. Incidentally, when the stage 23 is transported into the vacuum chamber 21 and is located on the heater 22, the stage 23 moves downward by the stage movement mechanism 26 and comes into intimate contact with the heater 22.

The evacuation unit 27 is an evacuation unit that evacuates a gas (or an atmosphere) in the vacuum chamber 21. The evacuation unit 27 includes an exhaust pipe 27a that communicates with the inside of the vacuum chamber 21, and a pump 27b that evacuates the atmosphere in the vacuum chamber 21 through the exhaust pipe 27a. The pump 27b is electrically connected to the controller 30, and sucks and evacuates the gas in the vacuum chamber 21 under control of the controller 30.

The first supply unit 28 is the supply unit that supplies an inert gas such as nitrogen to the pressure chamber H1 (see FIG. 11) in the vacuum chamber 21. The first supply unit 28 includes a supply pipe 28a that communicates with the pressure chamber H1 in the vacuum chamber 21, a gas supply source 28b that supplies the inert gas such as the nitrogen to the pressure chamber H1 through the supply pipe 28a, and a valve 28c interposed in the supply pipe 28a. The valve 28c is electrically connected to the controller 30, and opens and closes the supply pipe 28a under control of the controller 30. Incidentally, an on-off valve such, for example, as a solenoid valve or a butterfly valve is used as the valve 28c. The first supply unit 28 supplies the inert gas to the pressure chamber H1 in the vacuum chamber 21 through the supply pipe 28a according to the opening and closing of the valve 28c under control of the controller 30.

The second supply unit 29 is the supply unit that supplies the inert gas such as the nitrogen to the accommodation chamber H2 (see FIG. 11) in the vacuum chamber 21. The second supply unit 29 includes a supply pipe 29a that communicates with the accommodation chamber H2 in the vacuum chamber 21, a gas supply source 29b that supplies the inert gas such as the nitrogen to the accommodation chamber H2 through the supply pipe 29a, and a valve 29c interposed in the supply pipe 29a. The valve 29c is electrically connected to the controller 30, and opens and closes the supply pipe 29a under control of the controller 30. Incidentally, an on-off valve such, for example, as a solenoid valve or a butterfly valve is used as the valve 29c. The second supply unit 29 supplies the gas to the accommodation chamber H2 in the vacuum chamber 21 through the supply pipe 29a according to the opening and closing of the valve 29c under control of the controller 30.

The controller 30 includes a controller (not shown) that performs centralized control on parts, and a storage unit (not shown) that stores various programs, various data, and so on. RAM (random access memory) or nonvolatile memory that functions as a work area of the controller, a hard disk drive, or the like, for example, is used as the storage unit. The controller 30 performs control on the parts, a series of data processes for data calculation or processing, or the like, based on the various programs, the various data, and so on stored in the storage unit. In particular, the controller 30 executes the film laminating process for laminating the thermosetting resin film 2 on the sealing substrate K1. The film laminating process includes an evacuating process for evacuation, and a pressing process for pressing. Incidentally, the storage unit stores laminating conditions including evacuation conditions and pressing conditions.

Next, description will be given with regard to film laminating operation performed by the above-mentioned manufacturing apparatus 11. Incidentally, the controller 30 of the manufacturing apparatus 11 executes the film laminating process and controls the parts.

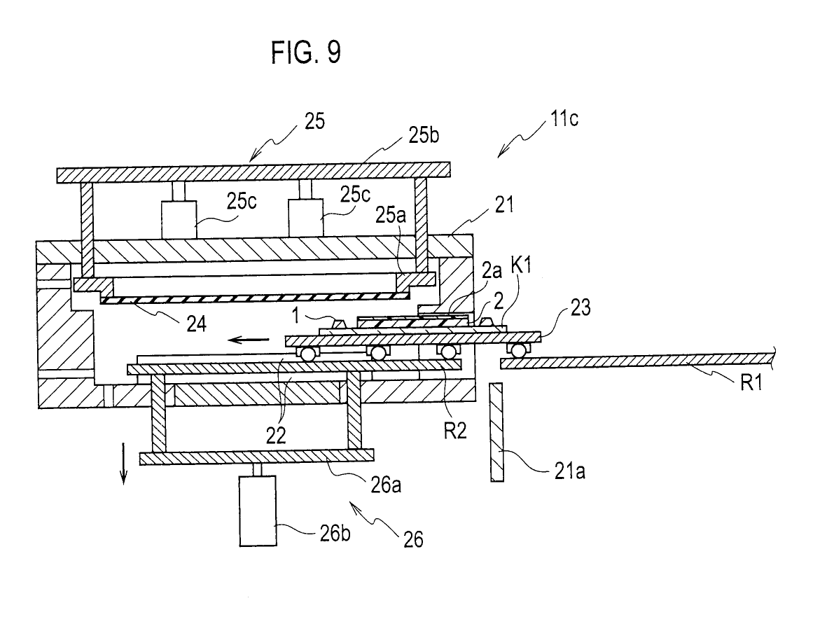

As shown in FIG. 9, under a condition where the elastic sheet 24 is in a saved position and the rails R2 are in a standby position, the stage 23 having mounted thereon a work (that is, the sealing substrate K1 on which the frit material 1 is baked and the thermosetting resin film 2 is laminated) is transported from the rails R1 through the opening by the open door 21a to the rails R2 in the vacuum chamber 21, and the stage 23 is located on the heater 22. Then, the rails R2 moves downward by the stage movement mechanism 26.

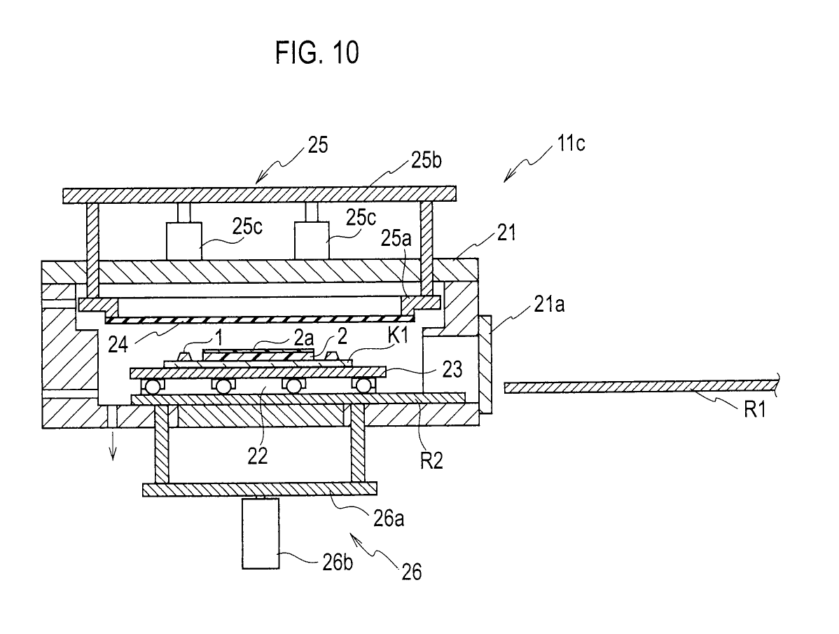

Thereby, as shown in FIG. 10, the stage 23 on the rails R2 comes into intimate contact with the heater 22. The heater 22 is maintained at a temperature such that the thermosetting resin film 2 softens on its surface. For this reason, the thermosetting resin film 2 on the sealing substrate K1 is heated through the stage 23 by heat of the heater 22. Thus, the surface thereof softens and the tackiness improves.

Then, as shown in FIG. 10, the door 21a of the vacuum chamber 21 is closed, and the vacuum chamber 21 becomes hermetic. Subsequently, the vacuum chamber 21 is evacuated by the evacuation unit 27. Thereby, the evacuation unit 27 is under a lower pressure (for example, under vacuum) than atmospheric pressure. By this evacuation, air bubbles existing between the sealing substrate K1 and the thermosetting resin film 2 move and are removed from a gap therebetween.

Then, as shown in FIG. 11, the elastic sheet 24 moves downward to a pressing location by the sheet movement mechanism 25 and partitions the vacuum chamber 21 into the pressure chamber H1 and the accommodation chamber H2. Subsequently, the inert gas (N₂) is supplied to the pressure chamber H1 by the first supply unit 28, and the elastic sheet 24 bulges downward and presses the thermosetting resin film 2 on the sealing substrate K1, against the sealing substrate K1, in a direction in which the thermosetting resin film 2 comes into intimate contact with the sealing substrate K1. By this pressing, the softened thermosetting resin film 2 is pressed against the sealing substrate K1 and comes into intimate contact with the sealing substrate K1. Also, air bubbles remaining even after the above-mentioned evacuation are forced out from the gap between the sealing substrate K1 and the thermosetting resin film 2 and are removed from the gap therebetween.

Here, the pressure of the inert gas injected can be controlled to arbitrarily adjust pressure in multiple stages. At this time, the pressure of the inert gas injected and the time of injection are managed. Incidentally, required pressure varies depending on laminating conditions for the thermosetting resin film 2, or the like.

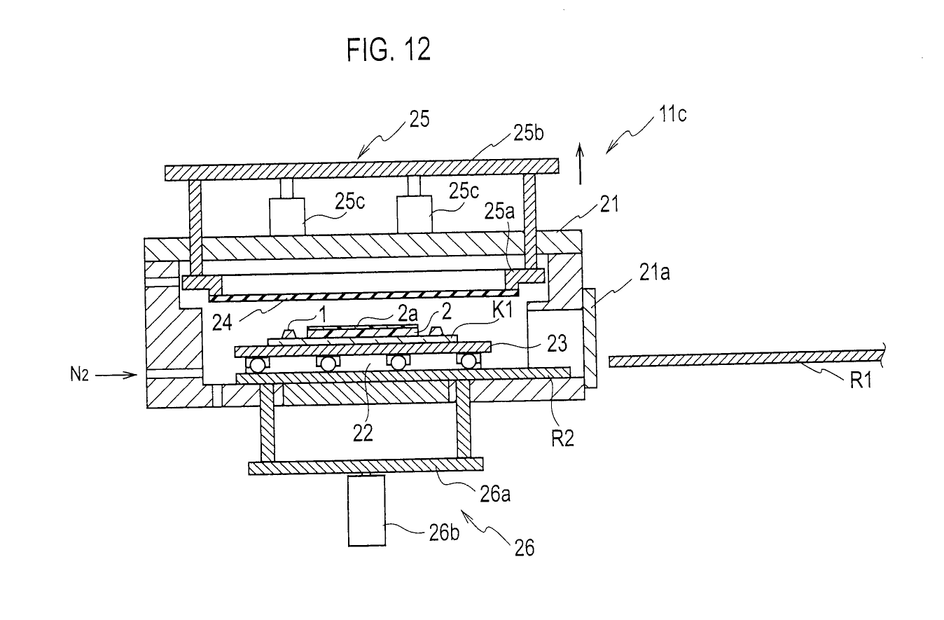

Finally, as shown in FIG. 12, the inert gas (N₂) is supplied to the accommodation chamber H2 in the vacuum chamber 21 by the second supply unit 29, and the accommodation chamber H2 is returned to the atmospheric pressure. Subsequently, the elastic sheet 24 moves upward to the save position by the sheet movement mechanism 25. Moreover, the rails R2 in the vacuum chamber 21 move upward by the stage movement mechanism 26, and the door 21a of the vacuum chamber 21 is opened. Under that condition, the stage 23 is transported from the rails R2 in the vacuum chamber 21 through the opening by the open door 21a onto the rails R1. The sealing substrate K1 is demounted from the stage 23 by the substrate transport robot in the transport apparatus 11f and is fed to the transport apparatus 11f. Subsequently, the sealing substrate K1 is transported to the sheet delaminating apparatus 11d in the following step.

Here, it is required that operation for laminating an adhesive film or the like to the glass substrate, laminating the glass substrates together by the adhesive film, or doing the like be performed in an atmosphere of an inert gas under vacuum, or in a controlled atmosphere in which temperature and relative humidity, dust or the like is controlled, in order to prevent the occurrence of air bubbles, the entry of dust therebetween or the like. Thus, a typical manufacturing apparatus adopts a structure in which a vacuum chamber is opened dividedly in upward and downward directions, the substrate is loaded under an air atmosphere, and then the vacuum chamber is closed so as to evacuate the vacuum chamber.

However, the manufacturing apparatus of such a structure has the structure in which the vacuum chamber is opened dividedly in the upward and downward directions and the substrate is loaded under the air atmosphere, and thus, if it is necessary to hold the substrate in the atmosphere of the inert gas or in the controlled atmosphere, a hermetic box or the like for surrounding the overall vacuum chamber must be additionally provided. Therefore, the vacuum chamber is given a divided structure while the hermeticity is maintained, and additionally, the provision of the hermetic box or the like is required, and further, if it is necessary to press the film or the substrate for lamination for enhancing the hermeticity, the structure of the apparatus becomes complicated, and also, the price of the apparatus becomes high.

On the other hand, according to the vacuum laminator 11c according to the first embodiment of the present invention, the elastic sheet 24 capable of partitioning the vacuum chamber 21 into the pressure chamber H1 and the accommodation chamber H2, and the first supply unit 28 that supplies the inert gas to the pressure chamber H1 are provided, and thereby, the elastic sheet 24 partitions the vacuum chamber 21 into two chambers while maintaining the hermeticity, and when the inert gas is supplied to the pressure chamber H1 that is one of the two chambers, the elastic sheet 24 bulges downward and presses the thermosetting resin film 2 on the sealing substrate K1, against the sealing substrate K1, in the direction in which the thermosetting resin film 2 comes into intimate contact with the sealing substrate K1. By this pressing, the softened thermosetting resin film 2 is pressed against and comes into intimate contact with the sealing substrate K1. Therefore, the provision of a complicated pressing mechanism or the like as is typical is not required, and further, it is not necessary to give the vacuum chamber the divided structure and provide the hermetic box or the like, while maintaining the hermeticity, and thus, complication of the structure of the apparatus and a rise in the price of the apparatus can be suppressed.

### Second Embodiment

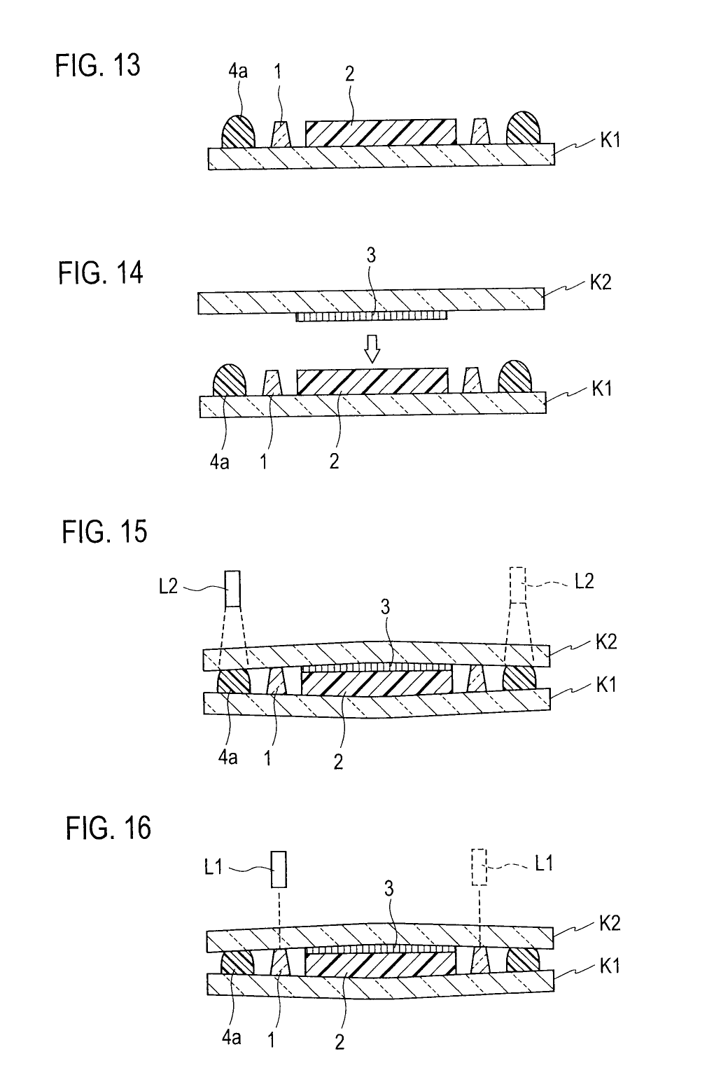

A second embodiment of the present invention will be described with reference to FIGS. 13 to 17.

The second embodiment of the present invention is basically the same as the first embodiment. For the second embodiment, therefore, description will be given with regard to different parts from the first embodiment. Incidentally, in the second embodiment, description of the same parts as described for the first embodiment will be omitted.

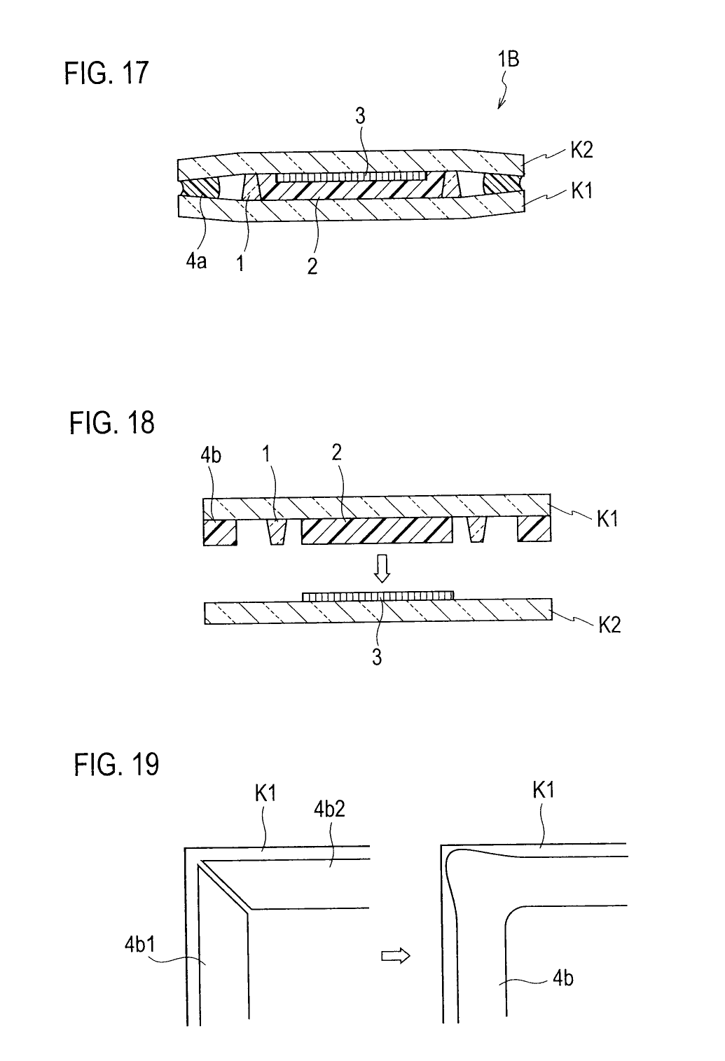

A process for manufacturing a flat-panel display device according to the second embodiment of the present invention includes, after the sheet delaminating process shown in FIG. 3 according to the first embodiment, a coating process for coating a sealant 4a in the shape of a frame both on the sealing substrate K1 after delamination of the protective sheet 2a and outside the frame-shaped frit material 1, as shown in FIG. 13; a lamination process for laminating the sealing substrate K1 coated with the sealant 4a to the element substrate K2, as shown in FIG. 14; a seal curing process for curing the frame-shaped sealant 4a situated between the sealing substrate K1 and the element substrate K2 laminated together, as shown in FIG. 15; a frit bonding process for bonding the frit material 1 to the element substrate K2 by melting the frame-shaped frit material 1 situated between the sealing substrate K1 having the cured sealant 4a and the element substrate K2 laminated together, as shown in FIG. 16; and a film curing process for heat-curing the thermosetting resin film 2 situated between the sealing substrate K1 and the element substrate K2 having the frit material 1 bonded thereto, as shown in FIG. 17.

In the coating process, as shown in FIG. 13, the sealant 4a that acts as a sealing material is coated in the shape of the frame both on the sealing substrate K1 after the delamination of the protective sheet 2a and outside the frame-shaped frit material 1. Thereby, the sealing material is formed on the sealing substrate K1, in a double-frame form as the sealant 4a and the frit material 1. In the coating process, a seal coating apparatus is used, and seal coating takes place in an atmosphere of an inert gas such as nitrogen. For instance, a dispenser head that dispenses the sealant 4a moves relatively to the sealing substrate K1, and the sealant 4a is coated in the shape of the frame on the sealing substrate K1. Incidentally, a photo-setting resin or the like, for example, is used as the sealant 4a.

In the lamination process, as shown in FIG. 14, the element substrate K2 is turned upside down so that the light-emitting elements 3 on the element substrate K2 face the thermosetting resin film 2 on the sealing substrate K1, and the element substrate K2 is mounted and laminated on the sealing substrate K1. In the lamination process, the laminator is used, and lamination takes place in a vacuum atmosphere. For instance, the sealing substrate K1 is mounted on the stage of the laminator, and the element substrate K2 is supported by the retainer of the laminator. Subsequently, alignment is provided between the sealing substrate K1 and the element substrate K2, the stage having the sealing substrate K1 mounted thereon moves toward the retainer retaining the element substrate K2, and the sealing substrate K1 and the element substrate K2 are laminated together in a vacuum atmosphere.

In the seal curing process, as shown in FIG. 15, the frame-shaped sealant 4a situated between the sealing substrate K1 and the element substrate K2 laminated together is cured by light irradiation. Also in the seal curing process, the laminator is used, and the light irradiation also takes place in a vacuum atmosphere. A laser irradiation unit L2 (see FIG. 15) provided in the laminator, for example, is used to apply the light to the frame-shaped sealant 4a situated between the sealing substrate K1 and the element substrate K2 laminated together and thereby cure the sealant 4a. In this way, the sealing substrate K1 and the element substrate K2 are joined (boned) together by the sealant 4a, and further, are fixed together by the frit material 1 in the following frit bonding process. Incidentally, if an ultraviolet-curing resin is used as the sealant 4a, a UV irradiation unit that provides ultraviolet irradiation is used.

Here, the frame-shaped sealant 4a is cured, and the internal space formed by the sealant 4a, the sealing substrate K1 and the element substrate K2 is sealed by the sealant 4a under vacuum. Thereby, in the following process, the sealing substrate K1 and the element substrate K2 having the cured sealant 4a can be exposed to the atmosphere, and thus, the following frit bonding process can be performed in the atmosphere without having to use a complicated apparatus for the use of vacuum or an inert gas in the following process. As a result, manufacture can be facilitated.

After the seal curing process, the frit bonding process shown in FIG. 16 and the film curing process shown in FIG. 17 are performed, and a flat-panel display device 1B is brought to completion. Here, the frit bonding process and the film curing process are the same as the first embodiment. Incidentally, in the flat-panel display device 1B, if it is necessary to cut off the sealant 4a, the sealant 4a is cut between the frame-shaped sealant 4a and the frit material 1, and the outer periphery of the sealing substrate K1 and the element substrate K2 having the cured thermosetting resin film 2 is cut off.

According to the second embodiment, as described above, the same effects as the first embodiment can be achieved. Further, the internal space formed by the sealant 4a, the sealing substrate K1 and the element substrate K2 is sealed by the sealant 4a under vacuum. Thus, in the following process, the sealing substrate K1 and the element substrate K2 having the cured sealant 4a can be exposed to the atmosphere. Thereby, the following frit bonding process can be performed in the atmosphere, and further, the need for the use of the complicated apparatus for the use of the vacuum or the inert gas is eliminated. Thus, the manufacture can be facilitated, and in addition, manufacturing costs can be reduced. Also, the frame-shaped sealant 4a improves adhesion between the sealing substrate K1 and the element substrate K2, and thus enables suppressing damage by shock and hence improving product reliability.

### Third Embodiment

A third embodiment of the present invention will be described with reference to FIGS. 18 to 22.

The third embodiment of the present invention is basically the same as the second embodiment. For the third embodiment, therefore, description will be given with regard to different parts from the second embodiment. Incidentally, in the third embodiment, description of the same parts as described for the second embodiment will be omitted.

As shown in FIG. 18, the sealing substrate K1 having a frame-shaped sealant 4b mounted thereon is turned upside down so that the thermosetting resin film 2 on the sealing substrate K1 faces the light-emitting elements 3 on the element substrate K2, and the sealing substrate K1 is mounted and laminated on the element substrate K2. The sealant 4b is a thermosetting resin film. The sealant 4b is mounted in the shape of the frame both on the sealing substrate K1 and outside the frame-shaped frit material 1, as is the case with the mounting of the thermosetting resin film 2 in the film laminating process according to the first embodiment.

Here, the thermosetting resin film that forms the sealant 4b is mounted in the shape of the frame on the sealing substrate K1, as shown in FIG. 19 (See the left-hand part of FIG. 19). At this time, plural seal pieces 4b1 and 4b2 are mounted as the sealant 4b on the sealing substrate K1. As mentioned above, four strips of seal pieces 4b1 and 4b2, for examples, form the frame-shaped sealants 4b thereby to facilitate alignment or handling thereof, as compared to the use of a single frame-shaped sealant 4b.

Also, the seal pieces 4b1 and 4b2 are mounted so as not to be continuous, with a gap therebetween, as shown in FIG. 19. This is for the purpose of smoothly evacuating the internal space formed by the sealant 4b, the sealing substrate K1 and the element substrate K2 in the following lamination process. After the completion of the lamination process, the seal pieces 4b1 and 4b2 are deformed and spread, and thus, the gaps disappear (See the right-hand part of FIG. 19). Thereby, the internal space formed by the sealant 4b, the sealing substrate K1 and the element substrate K2 is sealed under vacuum. Incidentally, the gap between the seal pieces 4b1 and 4b2 lies on a line passing a corner of the sealing substrate K1. This facilitates deformation of the seal pieces 4b1 and 4b2 and hence integration thereof without the gap.

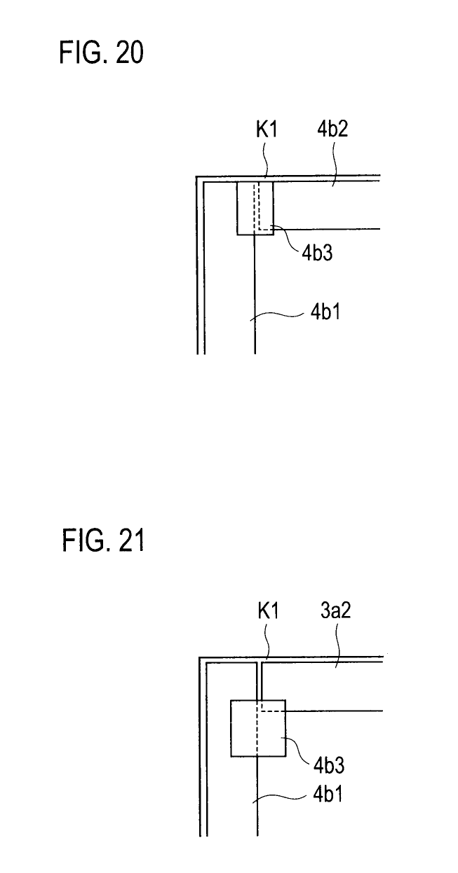

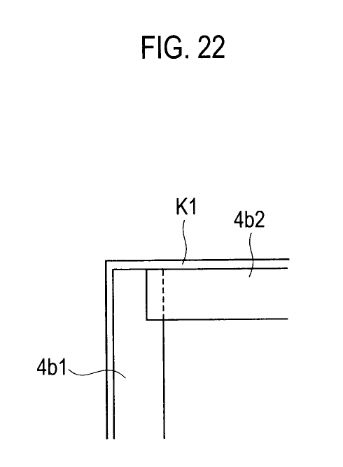

Incidentally, in the film laminating process, if the gap between the seal pieces 4b1 and 4b2 is judged as being large, or if there is a desire for more reliable sealing, another seal piece 4b3 is located on the gap and is mounted to overlap the seal pieces 4b1 and 4b2, as shown in FIGS. 20 and 21. Thereby, in the lamination process, load is concentrated on the overlapping seal piece 4b3, and the seal piece 4b3 is easily deformed and spread. Thus, the gap can be filled with reliability. Also, as shown in FIG. 22, a portion of the seal piece 4b2 may be mounted to overlap a portion of the seal piece 4b1. Also in this instance, in the lamination process, load is concentrated on the overlapping portion of the seal piece 4b2, and the seal piece 4b2 is easily deformed and spread. Thus, the gap can be filled with reliability.

Here, the mounting or overlapping mounting of the additional seal piece 4b3 facilitates forming a gap between the seal piece 4b3 and the element substrate K2 in the lamination process. Thus, performance in evacuation of the internal space formed by the sealant 4b, the sealing substrate K1 and the element substrate K2 can be improved. Also, in the lamination process, the amount of deformation of four corners of the sealing substrate K1 and the element substrate K2 can be increased thereby to increase the spreading of the film and hence improve the contact and adhesion between the films.

According to the third embodiment, as described above, the same effects as the second embodiment can be achieved. Moreover, the use of the thermosetting resin film as the sealant 4b enables the provision of the sealant 4b in the film laminating process. This enables omitting the coating process and the seal curing process and consequently enables a simplification of the manufacturing process, as compared to the use of the sealant 4a made of the photo-setting resin or the like. Also, the need for the seal coating apparatus or seal curing equipment is eliminated, and thus, the manufacturing costs can be reduced.

### Other Embodiments

Incidentally, it is to be understood that the present invention is not limited to the above-mentioned embodiments and that various changes may be made in the invention without departing from the gist of the invention. For instance, some structural elements may be deleted from all structural elements given in the above-mentioned embodiments. Moreover, structural elements throughout different embodiments may be appropriately combined. Also, in the above-mentioned embodiments, various numeric values are given; however, it is to be understood that the numeric values are exemplary only and the present invention is not so limited.

What is claimed is:

1. A method of manufacturing a flat-panel display device, comprising:
laminating a thermosetting resin film on a sealing substrate;
stacking the sealing substrate having the thermosetting resin film laminated thereon, and an element substrate having a light-emitting element together under a vacuum atmosphere with the thermosetting resin film and the light-emitting element facing inwardly, and with a frame-shaped sealing material around the thermosetting resin film interposed between the two substrates;
joining the sealing substrate and the element substrate together under a vacuum atmosphere by the sealing material situated between the sealing substrate and the element substrate stacked together; and
heat-curing the thermosetting resin film situated between the sealing substrate and the element substrate stacked together, under an air atmosphere.

2. The method of manufacturing the flat-panel display device according to claim 1,
wherein the sealing substrate having the thermosetting resin film laminated thereon, and the element substrate having a light-emitting element are stacked together by stacking the sealing substrate having the thermosetting resin film laminated thereon and the element substrate together with the sealing material interposed between the two substrates, by using, as the sealing material, a frame-shaped frit material and a frame-shaped sealant placed around the frit material, and
the sealing substrate and the element substrate are joined together by:
bonding the sealing substrate and the element substrate together under the vacuum atmosphere by the sealant situated between the sealing substrate and the element substrate stacked together; and
fixing the sealing substrate and the element substrate to each other by melting under the air atmosphere the frit material situated between the sealing substrate and the element substrate bonded together by the sealant.

3. The method of manufacturing the flat-panel display device according to claim 2,
wherein a film of the same type as the thermosetting resin film is used as the sealant.

4. The method of manufacturing the flat-panel display device according to claim 1,
wherein the thermosetting resin film is laminated on the sealing substrate by:
mounting the thermosetting resin film on the sealing substrate;
heating and softening the thermosetting resin film on the sealing substrate;
evacuating an ambient atmosphere around the softened thermosetting resin film; and
pressing the thermosetting resin film on the sealing substrate under a vacuum atmosphere in a direction in which the thermosetting resin film comes into intimate contact with the sealing substrate.

5. An apparatus for manufacturing a flat-panel display device, comprising:
a hermetic vacuum chamber having an openable/closable door;
a stage provided in the vacuum chamber;
a heater provided in the vacuum chamber and configured to heat the stage;
an elastic sheet provided in the vacuum chamber, and configured to be movable so as to partition the vacuum chamber into a pressure chamber that forms an enclosed space and an accommodation chamber that accommodates the heater and the stage;
a sheet movement mechanism configured to effect movement of the elastic sheet from outside the vacuum chamber;
an evacuation unit configured to evacuate the vacuum chamber; and
a first supply unit configured to supply an inert gas to the pressure chamber.

6. The apparatus for manufacturing the flat-panel display device according to claim 5, comprising a controller,
wherein, under control of the controller, the heater heats the stage, the evacuation unit evacuates the vacuum chamber with the stage heated, the sheet movement mechanism effects movement of the elastic sheet so as to partition the vacuum chamber into the pressure chamber and the accommodation chamber with the vacuum chamber evacuated, and the first supply unit supplies the inert gas to the pressure chamber with the elastic sheet partitioning the vacuum chamber into the pressure chamber and the accommodation chamber.

7. A flat-panel display device manufactured by a manufacturing method comprising:
laminating a thermosetting resin film on a sealing substrate;
stacking the sealing substrate having the thermosetting resin film laminated thereon, and an element substrate having a light-emitting element together under a vacuum atmosphere with the thermosetting resin film and the light-emitting element facing inwardly, and with a frame-shaped sealing material around the thermosetting resin film interposed the two substrates;
joining the sealing substrate and the element substrate together under a vacuum atmosphere by the sealing material situated between the sealing substrate and the element substrate stacked together; and
heat-curing the thermosetting resin film situated between the sealing substrate and the element substrate laminated together, under an air atmosphere.

8. The flat-panel display device manufactured by the manufacturing method according to claim 7,
wherein the sealing substrate having the thermosetting resin film laminated thereon, and the element substrate having a light-emitting element are stacked together by stacking the sealing substrate having the thermosetting resin film laminated thereon and the element substrate together with the sealing material interposed between the two substrates, by using, as the sealing material, a frame-shaped frit material and a frame-shaped sealant placed around the frit material, and
the sealing substrate and the element substrate are joined together by:
bonding the sealing substrate and the element substrate together under the vacuum atmosphere by the sealant situated between the sealing substrate and the element substrate stacked together; and
fixing the sealing substrate and the element substrate to each other by melting under the air atmosphere the frit material situated between the sealing substrate and the element substrate bonded together by the sealant.

9. The flat-panel display device manufactured by the manufacturing method according to claim 8,
wherein a film of the same type as the thermosetting resin film is used as the sealant.

10. The flat-panel display device manufactured by the manufacturing method according to claim 7,
wherein the thermosetting resin film is laminated on the sealing substrate by:
mounting the thermosetting resin film on the sealing substrate;
heating and softening the thermosetting resin film on the sealing substrate;
evacuating an ambient atmosphere around the softened thermosetting resin film; and
pressing the thermosetting resin film on the sealing substrate under a vacuum atmosphere in a direction in which the thermosetting resin film comes into intimate contact with the sealing substrate.
